(19) United States
(12) Patent Application Publication
(10) Pub. No.: US 2013/0240964 A1
(43) Pub. Date: Sep. 19, 2013

(54) MAGNETIC STORAGE APPARATUS

(71) Applicant: KABUSHIKI KAISHA TOSHIBA, Tokyo (JP)

(72) Inventors: Jyunichi OZEKI, Yokosuka-shi (JP); Nobutoshi AOKI, Yokohama-shi (JP)

(73) Assignee: KABUSHIKI KAISHA TOSHIBA, Tokyo (JP)

(21) Appl. No.: 13/780,660

(22) Filed: Feb. 28, 2013

(30) Foreign Application Priority Data
Mar. 16, 2012 (JP) 2012-061174

(51) Int. Cl. G11C 11/16

(52) U.S. Cl. CPC G11C 11/161
USPC 257/295

(57) ABSTRACT

According to one embodiment, there is provided a magnetic storage apparatus that includes a magnetic resistance effect element with a ferromagnetic storage layer and a ferromagnetic reference layer, and a selective transistor connected to the magnetic resistance effect element. The magnetic resistance effect element has a resistance varied in accordance with a magnetization state of the ferromagnetic storage layer. The selective transistor is connected to the magnetic resistance effect element. The gate electrode of the selective transistor at least has a portion formed of a ferromagnetic layer magnetized in a direction opposite to the direction of magnetization of the ferromagnetic reference layer.

### CROSS-REFERENCE TO RELATED APPLICATIONS

This application is based upon and claims the benefit of priority from Japanese Patent Application No. 2012-061174, filed Mar. 16, 2012, the entire contents of which are incorporated herein by reference.

### FIELD

Embodiments described herein relate generally to a magnetic storage apparatus using a magnetoresistive element.

### BACKGROUND

Attention is currently attracted to a magnetoresistive random access memory (MRAM), as a type of nonvolatile semiconductor memory, utilizing a magnetoresistive element such as a magnetic tunnel junction (MTJ) element. This magnetoresistive random access memory has significant advantages that it is completely non-volatile, an extremely number of data rewriting is possible, and nondestructive reading is possible without refreshing operations.

A storage layer and a reference layer, which provide the MTJ element, are formed of a magnetic material and produce a magnetic field to the outside. In general, in a vertical magnetization type of MTJ, the leakage field produced by the reference layer is significantly greater than that of an inplane magnetization type. Further, the storage layer having a smaller magnetism holding force than the reference layer is strongly affected by the leakage field from the reference layer. More specifically, by the influence of the leakage field from the reference layer, an inversion current value necessary for writing is increased to thereby reduce thermal stability.

### BRIEF DESCRIPTION OF THE DRAWINGS

FIG. 1 is a schematic sectional view illustrating a magnetic storage apparatus according to a first embodiment;

FIG. 2 is a sectional view illustrating a specific structure of an MTJ element;

FIG. 3 is a view illustrating a calculation model for calculating the dependency of a leakage field in the structure of FIG. 1 on the distance between a gate element and the MTJ;

FIG. 4 is a graph indicating the calculation result associated with the dependency of the leakage field in the structure of FIG. 1 on the distance between the gate element and the MTJ;

FIG. 5 is a schematic sectional view illustrating a magnetic storage apparatus according to a second embodiment;

FIG. 6 is a view illustrating a calculation model for calculating the dependency of a leakage field in the structure of FIG. 5 on the distance between a gate element and the MTJ;

FIG. 7 is a graph indicating the calculation result associated with the dependency of the leakage field in the structure of FIG. 5 on the distance between the gate element and the MTJ;

FIG. 8 is a schematic sectional view illustrating a magnetic storage apparatus according to a third embodiment; and

FIG. 9 is a schematic sectional view illustrating a magnetic storage apparatus according to a fourth embodiment.

### DETAILED DESCRIPTION

In general, according to one embodiment, there is provided a magnetic storage apparatus comprising: a magnetic resistance effect element including a ferromagnetic storage layer and a ferromagnetic reference layer, the ferromagnetic storage layer having a direction of magnetization thereof varied by a spin polarized current, the ferromagnetic reference layer having a constant direction of magnetization, the magnetic resistance effect element having a resistance varied in accordance with a magnetization state of the ferromagnetic storage layer; and a selective transistor connected to the magnetic resistance effect element, and having a gate electrode, the gate electrode at least having a portion formed of a ferromagnetic layer magnetized in a direction opposite to the direction of magnetization of the ferromagnetic reference layer.

Embodiments of the invention will be described with reference to the accompanying drawings.

### First Embodiment

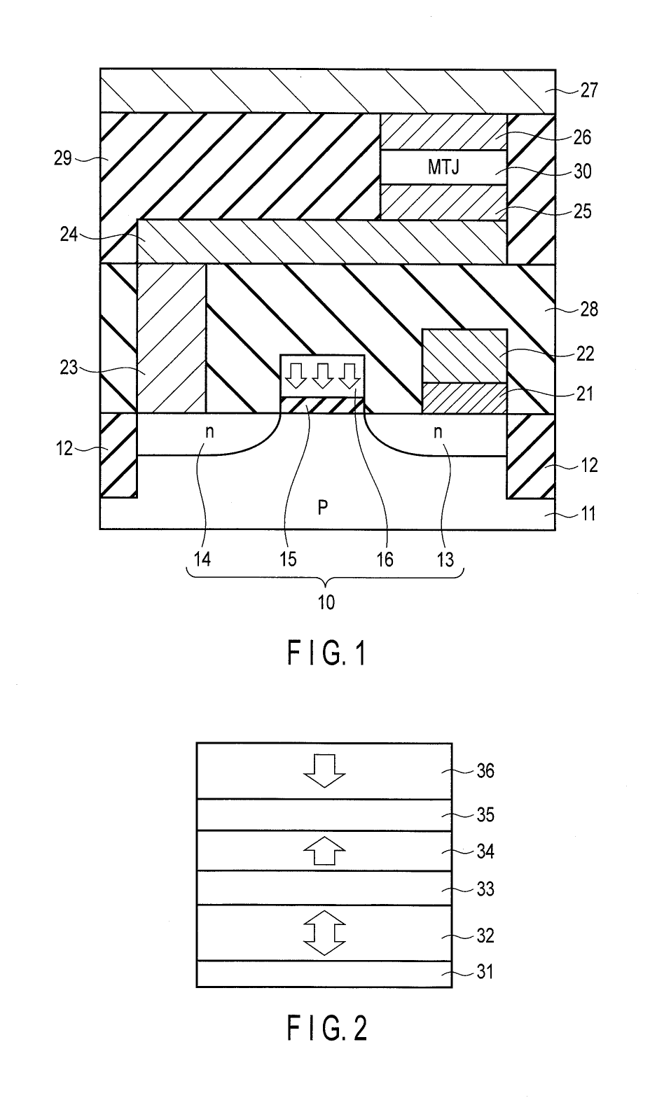

FIG. 1 is a schematic sectional view illustrating a magnetic storage apparatus according to a first embodiment.

This embodiment is an example where an MRAM is formed of a single MTJ element and a single selective transistor. Although FIG. 1 shows only one MRAM, a plurality of MRAMs are actually arranged in a matrix.

An element isolation insulating layer 12 is provided in a surface region of a semiconductor substrate 11 formed of, for example, p-type Si. The surface region of the semiconductor substrate 11 surrounded by the element isolation insulating layer 12 serves as an active area for forming an element. The element isolation insulating layer 12 is formed of, for example, a Shallow Trench Isolation (STI) structure. The STI structure is, for example, silicon oxide.

A selective transistor 10 is formed in the active area of the semiconductor substrate 11. The selective transistor 10 comprises a source area 13 and a drain area 14 separate from each other. The source area 13 and the drain area 14 are n⁺ diffusion areas formed by implanting a high-density n⁺ impurity into the semiconductor substrate 11. A gate insulating film 15 formed of, for example, silicon oxide is provided on a portion of the semiconductor substrate 11 that will serve as a channel between the source area 13 and the drain area 14, and a gate electrode 16 is provided on the gate insulating film 15. The gate electrode 16 serves as a word line WL. A wiring layer 22 of Al or Cu is provided on the source area 13 via a contact 21 formed of, for example, polysilicon. The wiring layer 22 functions as a bit line /BL. A lead wire 24 is provided on the drain area 14 via a contact 23.

An MTJ element 30 is provided on the lead wire 24, held between a lower electrode 25 and an upper electrode 26. A wiring layer 27 is provided on the upper electrode 26. The wiring layer 27 functions as a bit line BL. Further, interlayer insulating layers 28 and 29 formed of, for example, silicon oxide, are buried between the semiconductor substrate 11 and the wiring layer 27.

The above-described basic structure is similar to that of a general MRAM. This embodiment is, however, characterized in that the gate element 16 is formed of a magnetic material with vertical magnetization (hereinafter, referred to simply as a “gate electrode magnetic layer”), in addition to the structure of the general MRAM. In this case, the gate electrode magnetic layer 16 has a function as a word line and as a shift adjusting layer.

FIG. 2 is a sectional view illustrating the structure of the MTJ element 30. As shown, the MTJ element 30 has a structure in which an underlayer layer 31, a storage layer 32, a tunnel barrier layer 33, a reference layer 34, a nonmagnetic metal layer 35 and a shift adjusting layer 36, are stacked in this order on the lower electrode 25. The storage layer 32 has its magnetization direction varied when an external magnetic field (spin-polarized current) is applied, while the reference layer 34 and the shift adjusting layer 36 are kept constant in the direction of magnetization regardless of the external magnetic field. The storage layer 32, the reference layer 34 and the shift adjusting layer 36 are formed of, for example, an alloy of CoFe, the tunnel barrier layer 33 is formed of, for example, MgO, and the non-magnetic metal layer 35 is formed of, for example, Ru. Further, the storage layer 32 has a thickness of, for example, 2 nm, the reference layer 34 and the shift adjusting layer 36 have a thickness of, for example, 6 nm, and the tunnel barrier layer 33 and the non-magnetic metal layer 35 have a thickness of, for example, 1 nm.

When the reference layer 34 is formed of a magnetic material having in-plane anisotropy, it is appropriate to also form the shift adjusting layer 36 and the gate electrode magnetic layer 16 of a magnetic material having in-plane anisotropy. In contrast, if the reference layer 34 is formed of a magnetic material having vertical anisotropy, it is appropriate to also form the shift adjusting layer 36 and the gate electrode magnetic layer 16 of a magnetic material having vertical anisotropy.

A description will now be given of a case where the reference layer 34 is formed of a magnetic material having vertical anisotropy, and the gate electrode magnetic layer 16 is also formed of a magnetic material having vertical anisotropy. Assume here that the direction of magnetization of the reference layer 34 is set to a direction of +z. If the direction of the vertical magnetization of the gate electrode magnetic layer 16 can be made opposite to that of the reference layer 34, a desired leakage field cancelling effect can be obtained. In view of this, the direction of magnetization of the gate electrode magnetic layer 16 is set to a direction of −z to obtain the desired leakage field cancelling effect.

A description will now be given of the vertical magnetization material used for the gate electrode magnetic layer 16.

The vertical magnetization material used for the gate electrode magnetic layer 16 in the embodiment basically contains at least one material selected from a group consisting of Fe (iron), Co (cobalt), Ni (nickel) and Mn (manganese), and at least one material selected from a group consisting of Pt (platinum), Pd (palladium), Ir (iridium), Rh (rhodium), Os (osmium), Au (gold), Ag (silver), Cu (copper) and Cr (chromium). Further, to adjust saturated magnetization, to control crystal magnetic anisotropy energy and to adjust grain size and coupling of crystal grains, at least one material selected from a group consisting of B (boron), C (carbon), Si (silicon), Al (aluminum), Mg (magnesium), Ta (tantalum), Zr (ziruconium), Ti (titanium), Hf (hafnium), Y (yttrium) and a rare-earth element, may be added.

As a material containing Co as the main ingredient, a Co—Cr—Pt alloy, a Co—Cr—Ta alloy, a Co—Cr—Pt—Ta alloy, etc., which have a Hexagonal Closest Packing (HCP) structure, can be used. If the compositions of the alloys are adjusted, the alloys can adjust the saturated magnetization within a range of from not less than 800 emu/cc to less than 1400 emu/cc, and can adjust the crystal magnetic anisotropy energy within a range of from not less than 1×10⁵ erg/cc to less than 1×10⁷ erg/cc.

When the Co—Pt alloy has a composition close to Co₅₀Pt₅₀ (at %), an ordered alloy of L10-CoPt is formed. This ordered alloy has a Face-Centered Tetragonal (FCT) structure.

As a material containing Fe as the main ingredient, an Fe—Pt alloy or an Fe—Pd alloy can be used. In particular, the Fe—Pt alloy is ordered if it has a composition of Fe₅₀Pt₅₀ (at %) and has an L10 structure with the FCT structure as a basic structure. In this state, the Fe—Pt alloy can have a high crystal magnetic anisotropy energy of not less than 1×10⁷ erg/cc.

Before ordering, the Fe₅₀Pt₅₀ alloy has a Face-Centered Cubic (FCC) structure, and exhibits a crystal magnetic anisotropy energy of only 1×10⁶ erg/cc. Thus, by adjusting an annealing temperature and a composition, controlling the degree of order, and adding additives, the crystal magnetic anisotropy energy can be adjusted within a range of from not less than 5×10⁵ erg/cc to not more than 5×10⁸ erg/cc.

More specifically, by adding Cu or V (vanadium) to the Fe—Pt alloy, the saturated magnetization (Ms) and crystal magnetic anisotropy energy (Ku) can be controlled.

Further, where an Fe—Pt ordered alloy is formed, if a multi-layer structure of [Fe/Pt]n (n: a positive integer) is formed, an Fe—Pt ordered alloy of substantially an ideal order can be formed. In this case, it is desirable to set the thickness of each of the Fe and Pt layers within a range of from not less than 0.1 nm to not more than 1 nm. This is indispensable to create a uniform composition state. In the case of ordering an Fe—Pt alloy, martensitic transformation from the FCC structure to the FCT structure is accompanied, which accelerates the transformation. Thus, the ordering is important.

Further, the Fe—Pt alloy ordering temperature is as high as 500° C. or more, and hence the resultant alloy has a high thermal resistance. This point is very preferable because it means that the resultant alloy can sufficiently resist an annealing process performed thereon later. The ordering temperature can be reduced by an additive such as Cu or V.

Yet further, the electrical resistance ρ (Ωm) of the vertical magnetization material used for the gate electrode magnetic layer 16 of the embodiment is suppressed to such a low value as ρ=6.0×10⁻⁸ Ωm, if the material contains Co as the main ingredient. This value is approx 2.2 to 2.3 times the electrical resistance of Cu or Al often used for low resistance wires.

A description will be given of a simulation result obtained in the embodiment by simulating the leakage field due to the gate electrode magnetic layer 16.

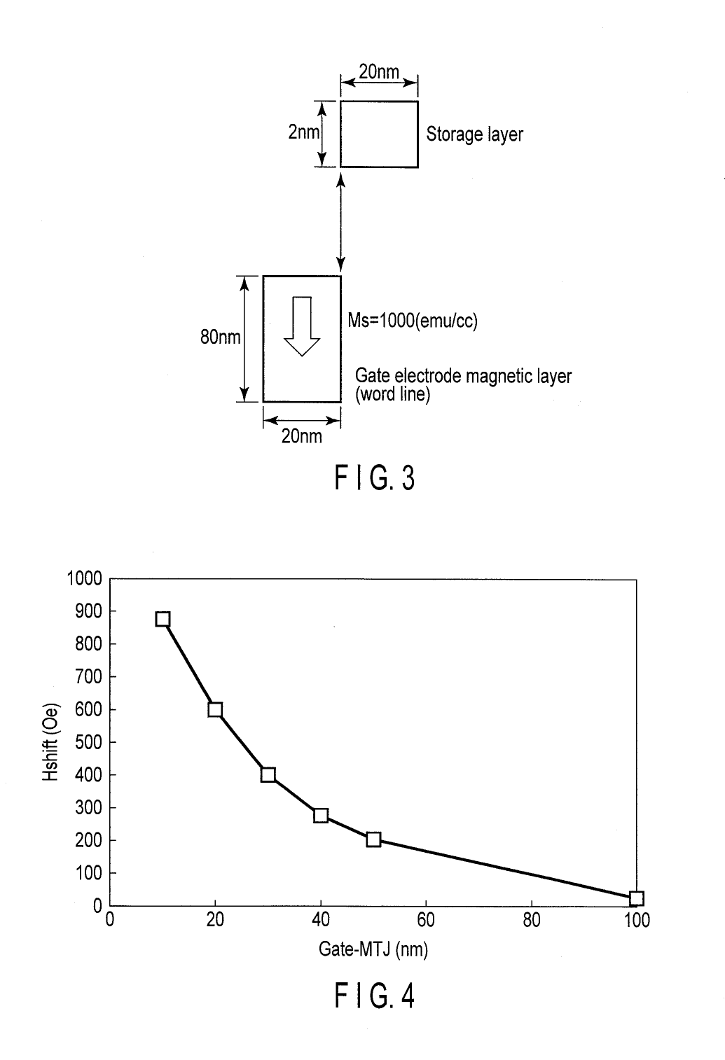

The film-surface vertical component of the leakage field applied to the storage layer 32 by the gate electrode magnetic layer 16 was obtained by micromagnetic simulation. As shown in FIG. 3, the diameter of a cylindrical MTJ element 30 was set to 20 nm, and the width and thickness of the gate electrode magnetic layer 16 were set to 20 nm and 80 nm, respectively. Further, the magnetic parameters used for the simulation, i.e., the saturated magnetization Ms₁, magnetic anisotropic constant Ku₁ and film thickness t₁ of the storage layer 32, were set to Ms₁=670 (emu/cm³), Ku₁=3.5×10⁶ (erg/cm³), and t₁=2 nm, respectively. Also, the saturated magnetization Ms₂ and magnetic anisotropic constant Ku₂ of the gate electrode magnetic layer 16 were set to Ms₂=1000 (emu/cm³) and Ku₂=20.0×10⁶ (erg/cm³), respectively.

FIG. 4 shows the dependency (obtained in the simulated case), on the distance between the gate electrode and the MTJ element, of the film-surface vertical component of the leakage field applied to the storage layer 32 by the gate electrode magnetic layer 16. From FIG. 4, it can be understood that the shorter the distance between the gate electrode and the MTJ element, the greater the leakage field from the gate electrode magnetic layer 16, namely, the greater the effect of canceling the leakage field from the reference layer 34. Thus, in accordance with a reduction in the distance between the gate electrode and the MTJ element, the leakage field generated by the reference layer 34 can be further suppressed. From the simulation result, it is understood that the thickness and material of the gate electrode magnetic layer 16, and the distance between the gate electrode and the MTJ element, should be determined so as to cancel the leakage field applied to the storage layer 32 by the reference layer 34, using the leakage fields from the shift adjusting layer 36 and the gate electrode magnetic layer 16.

As described above, since in the first embodiment, the gate electrode 16 of the selective transistor 10 is formed of a ferromagnetic layer magnetized in the direction opposite to the magnetization direction of the reference layer 34 of the MTJ element 30, the influence of the leakage field from the reference layer 34 can be canceled in the storage layer 32. As a result, the inversion current necessary for writing can be reduced, and the thermal stability of the storage layer 32 can be enhanced. In other words, the first embodiment can realize a non-volatile MRAM, in which the current necessary for writing data in the storage layer 32 can be reduced with the thermal stability of the layer 32 maintained, and the thermal disturbance resistance of bit information can be maintained even when the memory cell is further micro-fabricated.

Further, since in the first embodiment, the gate electrode magnetic layer 16 also has a shift adjusting function, the shift adjusting layer 36 itself can be made thin, which is free from a disadvantage, occurring when the layer 36 is formed thick, that the direction of magnetization may be deviated from the vertical magnetization. Furthermore, since the shift adjusting layer 36 cannot be made too thick in view of fabrication, the fact that the layer 36 can be made thin is rather advantageous.

### Second Embodiment

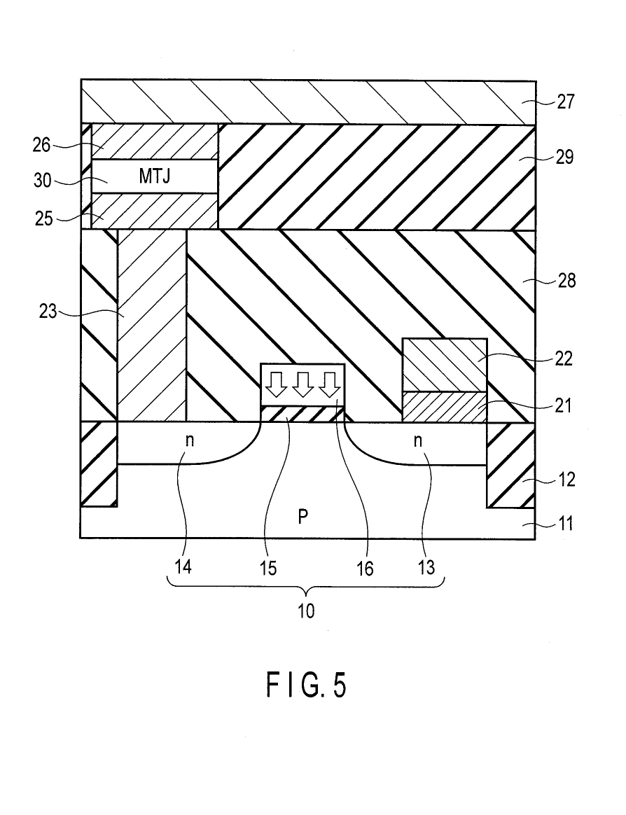

FIG. 5 is a schematic sectional view illustrating a magnetic storage apparatus according to a second embodiment. In FIG. 5, elements similar to those of the embodiment shown in FIG. 1 are denoted by corresponding reference numbers, and no detailed description will be given thereof.

The second embodiment differs from the first embodiment in that in the former, an MTJ element 30 is directly connected to a contact 23 without using a lead wire 24. Namely, in the second embodiment, the contact 23 is provided on the drain area 14, and the MTJ element 30 is provided above the contact 23 between the lower and upper electrodes 25 and 26.

The other structures of the second embodiment are similar to those of the first embodiment shown in FIG. 1, and the structure of the MTJ element 30 is similar to that of the first embodiment shown in FIG. 2.

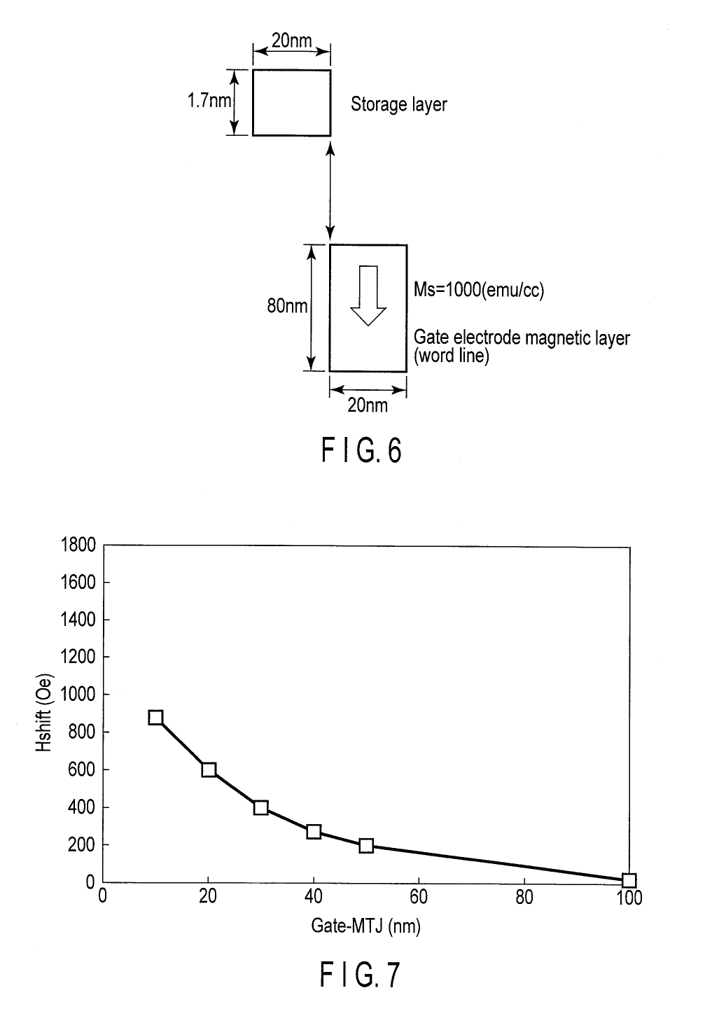

In this structure, the film-surface vertical component of the leakage field applied to the storage layer 32 by the gate electrode magnetic layer 16 was obtained by micromagnetic simulation. As shown in FIG. 6, the diameter of the cylindrical MTJ element 30 was set to 20 nm, and the width and thickness of the gate electrode magnetic layer 16 were set to 20 nm and 80 nm, respectively. Further, the magnetic parameters used for the simulation, i.e., the saturated magnetization Ms₁, magnetic anisotropic constant Ku₁ and film thickness t₁ of the storage layer 32, were set to Ms₁=670 (emu/cm³), Ku₁=3.5×10⁶ (erg/cm³), and t₁=2 nm, respectively. Also, the saturated magnetization Ms₂ and magnetic anisotropic constant Ku₂ of the gate electrode magnetic layer 16 were set to Ms₂=1000 (emu/cm³) and Ku₂=20.0×10⁶ (erg/cm³), respectively.

FIG. 7 shows the dependency (obtained in the simulated case), on the distance between the gate electrode and the MTJ element, of the film-surface vertical component of the leakage field applied to the storage layer 32 by the gate electrode magnetic layer 16. From FIG. 7, it can be understood that the shorter the distance between the gate electrode and the MTJ element, the greater the leakage field from the gate electrode magnetic layer 16, namely, the greater the effect of canceling the leakage field from the reference layer 34. Thus, in accordance with a reduction in the distance between the gate electrode and the MTJ element, the leakage field generated by the reference layer 34 can be further suppressed.

From the simulation result, it is understood that even where the MTJ element 30 is directly connected to the contact 23, the leakage field from the reference layer 34 can be canceled by forming the gate electrode 16 of the selective transistor 10 of a ferromagnetic layer magnetized in the direction opposite to the magnetization direction of the reference layer 34 of the MTJ element 30. As a result, the same advantages as those of the first embodiment can be obtained.

### Third Embodiment

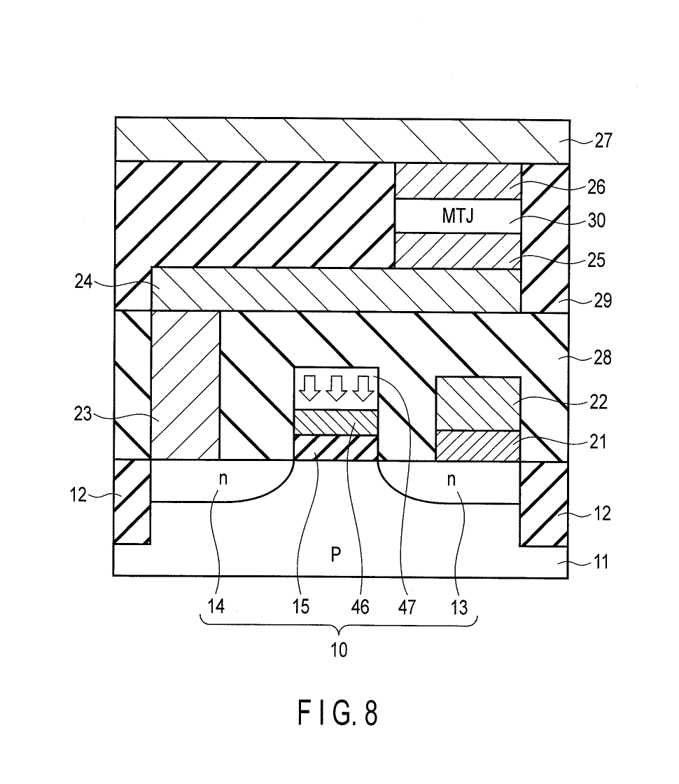

FIG. 8 is a schematic sectional view illustrating a magnetic storage apparatus according to a third embodiment. In FIG. 8, elements similar to those of the embodiment shown in FIG. 1 are denoted by corresponding reference numbers, and no detailed description will be given thereof.

The third embodiment differs from the first embodiment in the structure of a gate electrode section incorporated in the selective transistor 10. Namely, in the third embodiment, the gate electrode section has a structure in which a standard gate element 46 and a ferromagnetic layer 47 are stacked.

In this structure, the gate electrode 46 functions as a word line, and the ferromagnetic layer 47 contacting the gate electrode 46 functions as a shift adjusting layer. By virtue of this structure, even when a vertical magnetic material having a high resistance is used, this disadvantage can be offset because the word line functions as the gate electrode.

The film-surface vertical component of the leakage field applied to the storage layer 32 by the ferromagnetic layer 47 of the gate electrode section was obtained by micromagnetic simulation. The same magnetic parameter values as those in the first embodiment were used for the simulation. Further, in this case, the dependency, on the distance between the gate electrode and the MTJ element, of the film-surface vertical component of the leakage field applied to the storage layer 32 was measured. As a result, the same characteristic as shown in FIG. 4 was obtained. Namely, it is understood that in accordance with a reduction in the distance between the gate electrode and the MTJ element, the leakage field from the magnetic layer 47 of the gate electrode section is increased, which increases the effect of canceling the leakage field generated by the reference layer 34.

Thus, also in the third embodiment where the influence of the leakage field from the reference layer 34 is canceled using the ferromagnetic layer 47 of the gate electrode section, the same advantages as those of the first embodiment can be obtained. Further, since in the third embodiment, the gate electrode section has a two-layer structure comprising the gate electrode 46 and the ferromagnetic layer 47, another advantage that the degree of freedom for selecting the materials of the gate electrode 46 and the ferromagnetic layer 47 is enhanced can be obtained. Moreover, since the ferromagnetic layer 47 separate from the gate electrode 46 is provided, it can be located only at a necessary portion close to the magnetoresistance effect element 30.

### Fourth Embodiment

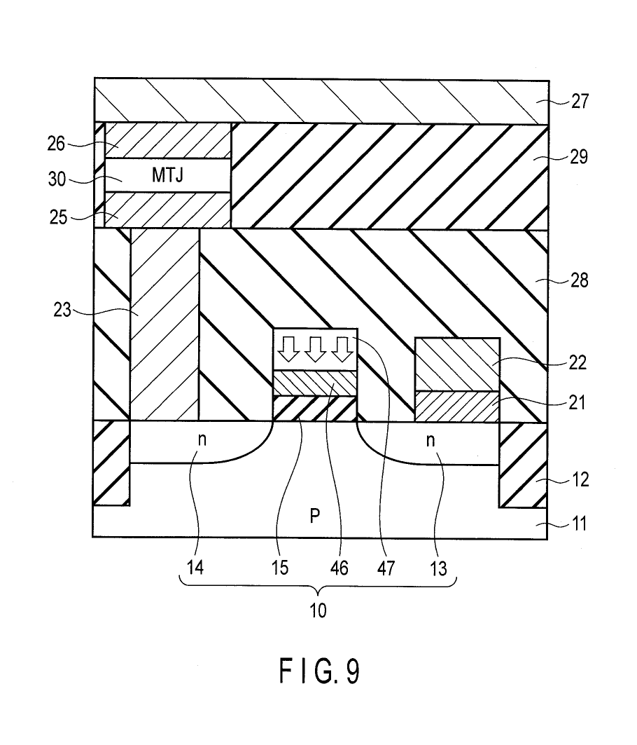

FIG. 9 is a schematic sectional view illustrating a magnetic storage apparatus according to a fourth embodiment. In FIG. 9, elements similar to those of the embodiment shown in FIG. 5 are denoted by corresponding reference numbers, and no detailed description will be given thereof.

The fourth embodiment differs from the above-described second embodiment in the structure of a gate electrode section incorporated in the selective transistor 10. Namely, the gate electrode section has a structure in which a standard gate element 46 and a ferromagnetic layer 47 are stacked.

In this structure, the gate electrode 46 functions as a word line, and the ferromagnetic layer 47 contacting the gate electrode 46 functions as a shift adjusting layer. By virtue of this structure, even when a vertical magnetic material having a high resistance is used, this disadvantage can be offset because the word line functions as the gate electrode.

The film-surface vertical component of the leakage field applied to the storage layer 32 by the ferromagnetic layer 47 of the gate electrode section was obtained by micromagnetic simulation. The same magnetic parameter values as those in the second embodiment were used for the simulation. Further, in this case, the dependency, on the distance between the gate electrode and the MTJ element, of the film-surface vertical component of the leakage field applied to the storage layer 32 was measured. As a result, the same characteristic as shown in FIG. 7 was obtained. Namely, it is understood that in accordance with a reduction in the distance between the gate electrode and the MTJ element, the leakage field from the magnetic layer 47 of the gate electrode section is increased, which increases the effect of canceling the leakage field generated by the reference layer 34.

Thus, the fourth embodiment can provide the same advantages as the second embodiment. Further, since in the fourth embodiment, the gate electrode section has a two-layer structure comprising the gate electrode 46 and the ferromagnetic layer 47, the same advantage as that of the third embodiment can also be obtained.

### (Modification)

The invention is not limited to the above-described embodiments.

The MTJ element, employed as a magnetic resistance effect element in the embodiments, is not limited to the structure shown in FIG. 2, but may be modified in accordance with the specifications. Further, a GMR element may be used as the magnetic resistance effect element. Yet further, the invention is also applicable to a magnetic resistance effect element other than the MTJ element or the GMR element. The invention is applicable to a magnetic resistance effect element that has a storage layer and a reference layer and suffers a leakage field from the reference layer.

Also, as described above, the shift adjusting layer can be made thin by making the gate electrode section also have a shift adjusting function. If the shift adjusting function of the gate electrode section is made sufficient, the shift adjusting layer itself can be omitted. This leads to simplification of the structure of the magnetic resistance effect element, and hence to simplification of the manufacturing process.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A magnetic storage apparatus comprising:
a magnetic resistance effect element including a ferromagnetic storage layer and a ferromagnetic reference layer, the ferromagnetic storage layer having a direction of magnetization thereof varied by a spin polarized current, the ferromagnetic reference layer having a constant direction of magnetization, the magnetic resistance effect element having a resistance varied in accordance with a magnetization state of the ferromagnetic storage layer; and
a selective transistor connected to the magnetic resistance effect element, and having a gate electrode, the gate electrode at least having a portion formed of a ferromagnetic layer magnetized in a direction opposite to the direction of magnetization of the ferromagnetic reference layer.

2. The apparatus according to claim 1, wherein the gate electrode is formed of a conductive ferromagnetic layer magnetized in a direction opposite to the direction of magnetization of the ferromagnetic reference layer.

3. The apparatus according to claim 1, wherein the gate electrode has a laminated structure including a non-magnetic metal layer and a ferromagnetic layer, the ferromagnetic layer being magnetized in the direction opposite to the direction of magnetization of the ferromagnetic reference layer.

4. The apparatus according to claim 1, wherein the magnetic resistance effect element is a magnetic tunnel junction element held between the ferromagnetic storage layer and the ferromagnetic reference layer with insulating layers interposed.

5. The apparatus according to claim 1, wherein the magnetic resistance effect element is located near the selective transistor, and is connected to a drain area of the selective transistor via a contact connected to the drain area and a lead wire connected to the contact.

6. The apparatus according to claim 5, further comprising an upper electrode provided on an upper surface of the magnetic resistance effect element, and a lower electrode provided on a lower surface of the magnetic resistance effect element, the lower electrode being connected to the lead wire.

7. The apparatus according to claim 1, wherein the magnetic resistance effect element is located near the selective transistors, and is connected to the drain area of the selective transistor via a contact.

8. The apparatus according to claim 7, further comprising an upper electrode provided on an upper surface of the magnetic resistance effect element, and a lower electrode provided on a lower surface of the magnetic resistance effect element, the lower electrode being connected to the contact.

9. The apparatus according to claim 1, further comprising a shift adjusting layer used to reduce a leakage field leaking from the ferromagnetic reference layer to the ferromagnetic storage layer.

10. The apparatus according to claim 9, wherein the ferromagnetic reference layer, the shift adjusting layer and the gate electrode are formed of an in-plane anisotropic magnetic material.

11. The apparatus according to claim 9, wherein the ferromagnetic reference layer, the shift adjusting layer and the gate electrode are formed of a vertically anisotropic magnetic material.

12. The apparatus according to claim 1, wherein the selective transistor is formed on a semiconductor substrate, and an interlayer insulating film is formed on the semiconductor substrate to cover the selective transistor, and the magnetic resistance effect element is formed on the interlayer insulating film.

13. A magnetic storage apparatus comprising:
a selective transistor formed on a semiconductor substrate, and including a gate electrode, a source area and a drain area;
an interlayer insulating film formed on the semiconductor substrate to cover the selective transistor;
a contact formed through the interlayer insulating film and connected to the drain area; and
a magnetic resistance effect element formed on the interlayer insulating film and connected to the contact, the magnetic resistance effect element including a ferromagnetic storage layer and ferromagnetic reference layer, the ferromagnetic storage layer having a direction of magnetization thereof varied by a spin polarized current, the ferromagnetic reference layer having a constant direction of magnetization, the magnetic resistance effect element having a resistance varied in accordance with a magnetization state of the ferromagnetic storage layer,
the gate electrode at least having a portion formed of a ferromagnetic layer magnetized in a direction opposite to the direction of magnetization of the ferromagnetic reference layer.

14. The apparatus according to claim 13, wherein the gate electrode is formed of a conductive ferromagnetic layer magnetized in a direction opposite to the direction of magnetization of the ferromagnetic reference layer.

15. The apparatus according to claim 13, wherein the gate electrode has a laminated structure including a non-magnetic metal layer and a ferromagnetic layer, the ferromagnetic layer being magnetized in the direction opposite to the direction of magnetization of the ferromagnetic reference layer.

16. The apparatus according to claim 13, wherein the magnetic resistance effect element is a magnetic tunnel junction element formed by placing an insulation film between the ferromagnetic storage layer and the ferromagnetic reference layer.

17. The apparatus according to claim 13, wherein the magnetic resistance effect element is located near the selective transistor, and is connected to a drain area of the selective transistor via a contact connected to the drain area and a lead wire connected to the contact.

18. The apparatus according to claim 13, wherein the magnetic resistance effect element is located near the selective transistor, and is connected to a drain area of the selective transistor via a contact.

19. The apparatus according to claim 13, further comprising a shift adjusting layer used to reduce a leakage field leaking from the ferromagnetic reference layer to the ferromagnetic storage layer.
